(19) United States
(12) Patent Application Publication
(10) Pub. No.: US 2026/0173630 A1
(43) Pub. Date: Jun. 18, 2026

(54) LIGHT EMITTING DISPLAY DEVICE

(71) Applicant: LG Display Co., Ltd., Seoul (KR)

(72) Inventors: EunJi PARK, Paju-si (KR); MyungHo BAN, Paju-si (KR); KyungMin KIM, Paju-si (KR); Yonghee JO, Paju-si (KR)

(73) Assignee: LG Display Co., Ltd., Seoul (KR)

(21) Appl. No.: 19/306,866

(22) Filed: Aug. 21, 2025

(30) Foreign Application Priority Data
Dec. 17, 2024 (KR) 10-2024-0189206

(51) Int. Cl. H10H 29/855; H10H 29/49; H10H 29/80

(52) U.S. Cl. CPC H10H 29/855; H10H 29/49; H10H 29/8323

(57) ABSTRACT

A light emitting display device according to an example of the present disclosure includes a substrate having a plurality of pixels, a driving element layer on the substrate, a first planarization layer on the driving element layer, and a second planarization layer disposed within each pixel on the first planarization layer. An anode electrode is disposed on the second planarization layer, and an emission layer is disposed on the first planarization layer, the second planarization layer and the anode electrode. A cathode electrode is disposed on the emission layer. This structure supports enhanced light extraction by enabling emission through the substrate while maintaining pixel-level control through layered planarization and electrode configurations.

### CROSS-REFERENCE TO RELATED APPLICATIONS

This application claims the benefit of the Korean Patent Application No. 10-2024-0189206 filed on Dec. 17, 2024, which is hereby incorporated by reference in its entirety.

### BACKGROUND

### Technical Field

The present disclosure relates to a light emitting display device. In particular, the present disclosure relates to a bottom emission type light emitting display device having micro mirrors to enhance the light extraction efficiency.

### Description of the Related Art

Among the display devices, light emitting display devices may have the advantages of a wide viewing angle, excellent contrast, and fast response speed. The light emitting element used in a light emitting display device may have a light emitting layer made of organic or inorganic material between the anode electrode and the cathode electrode.

In the light emitting element, holes are supplied from the anode electrode and electrons are supplied from the cathode electrode, and then the electrons and holes combine at the emission layer to generate excitons. As the excitons change from the excited state to the ground state, the fluorescent molecules in the emission layer may emit light to express color.

### BRIEF SUMMARY

Some of the light emitted from the emission layer of the light emitting display device may not be emitted to the outside and may be lost due to total reflection within the electrode layer having a high refractive index, or due to total reflection occurring at the interface between the emission layer and the electrodes and/or the interface between the substrate and the air. The inventors of the present disclosure recognized that this may result in a problem of reduced light extraction efficiency.

To overcome these problems, methods are being developed to improve the light extraction efficiency of light emitting devices by forming microlenses or microcavity structures inside the devices. However, although these structures improve the luminous efficiency of light emitted in the vertical direction of the display device, they cannot extract light emitted in the horizontal direction into the vertical direction. Therefore, existing methods have limitations in improving light extraction efficiency, and the inventors of the present disclosure have proposed various embodiments to address the foregoing technical shortcomings in the related art.

For example, various embodiments of the present disclosure provide a bottom emission type light emitting display device that maximizes light extraction efficiency by extracting light generated from the emission layer to the outside, which would otherwise be trapped inside the device and disappear due to total reflection.

Various embodiments of the present disclosure provide a bottom emission type light emitting display device that improves brightness and light extraction efficiency by arranging a micro mirror structure on the edge of the light emitting area to maximize the area of the light emitting area.

Various embodiments of the present disclosure provide a bottom emission type light emitting display device that improves light extraction efficiency and enhances brightness per unit power consumption by extracting light that may be extinguished by total reflection phenomena from the central portion of the anode electrode.

Various embodiments of the present disclosure provide a bottom emission type light emitting display device in which a trench structure is disposed between pixels having a micro mirror structure so that the color purity is improved by blocking the lateral leakage current.

In order to accomplish the above-mentioned technical benefits of the present disclosure, a light emitting display device according to the present disclosure comprises: a substrate, a driving element layer, a first planarization layer, a second planarization layer, an anode electrode, an emission layer and a cathode electrode. The substrate includes a plurality of pixels. The driving element layer is disposed on the substrate. The first planarization layer is disposed on the driving element layer. the second planarization layer is disposed within each pixel on the first planarization layer. The anode electrode is disposed on the second planarization layer. The emission layer is disposed on the first planarization layer, the second planarization layer and the anode electrode. The cathode electrode is disposed on the emission layer.

In an example embodiment, the substrate further comprises: a first pixel and a second pixel neighboring each other; a first light emitting diode disposed at the first pixel; a second light emitting diode disposed at the second pixel; and a dummy anode electrode disposed between the first light emitting diode and the second light emitting diode.

In an example embodiment, the light emitting display device further comprises at least one trench disposed between the first light emitting diode and the second light emitting diode.

In an example embodiment, the light emitting display device further comprises: a trench depressed or recessed into the first planarization layer between the first light emitting diode and the dummy anode electrode.

The light emitting display device according to the present disclosure may have a structure in which almost all of the lights emitted from the emission layer may be extracted to the outside without being trapped and extinguished inside of the device, thereby providing a bottom emission type light emitting display device with maximized light extraction efficiency.

The light emitting display device according to the present disclosure may provide a bottom emission type light emitting display device that minimizes non-emission areas and improve light extraction efficiency by arranging micro mirrors (or reflectors) without using a bank covering the circumferences of the pixel electrode.

The light emitting display device according to the present disclosure may have a structure in which a high refractive layer having a similar refractive index to that of the anode electrode may be disposed under the anode electrode and a low refractive layer may be disposed under the anode electrode. Accordingly, a bottom emission type light emitting display device with further enhanced light extraction efficiency may be provided by extracting light that would otherwise be lost due to total reflection inside the central portion of the anode electrode to outside.

The light emitting display device according to the present disclosure may have a structure in which a trench is placed between adjacent pixels, so that the emission layer may be separated for each pixel. Accordingly, a bottom emission type light emitting display device with improved color purity may be provided by blocking and/or eliminating lateral leakage current generated due to connection of the emission layer.

The effects that may be obtained from the present disclosure are not limited to the effects mentioned above, and other effects that are not mentioned may be clearly understood by those skilled in the art to which this disclosure belongs from the description above.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a diagram illustrating a schematic structure of a light emitting display device according to the present disclosure.

FIG. 2 is a circuit diagram illustrating a structure of one pixel included in the light emitting display device according to an example of the present disclosure.

FIG. 3 is a plan view illustrating an arrangement structure of the pixels disposed in the light emitting display device according to an example of the present disclosure.

FIG. 4 is an enlarged cross-sectional view taken along line I-I′ in FIG. 3, for illustrating the structure of a light emitting display device according to an example of the present disclosure.

FIG. 5 is an enlarged cross-sectional view taken along line II-II′ in FIG. 3, for illustrating light paths in a light emitting display device according to an example of the present disclosure.

FIG. 6 is an enlarged cross-sectional view, taken along line II-II′ of FIG. 3, illustrating light paths in a light emitting display device according to a first embodiment of the present disclosure.

FIG. 7 is an enlarged cross-sectional view, taken along line II-II′ of FIG. 3, illustrating a structure of a light emitting display device according to a second embodiment of the present disclosure.

FIG. 8 is an enlarged cross-sectional view, taken along line II-II′ of FIG. 3, illustrating a structure of a light emitting display device according to a third embodiment of the present disclosure.

FIG. 9 is an enlarged cross-sectional view, taken along line II-II′ of FIG. 3, illustrating a structure of a light emitting display device according to the fourth embodiment of the present disclosure.

FIG. 10 is an enlarged plan view illustrating a structure of a light emitting display device according to a fifth embodiment of the present disclosure.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure may be sufficiently thorough and complete to assist those skilled in the art to fully understand the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout the specification unless otherwise specified. In the following description, where the detailed description of the relevant known function or configuration may unnecessarily obscure an important point of the present disclosure, a detailed description of such known function of configuration may be omitted.

Reference will now be made in detail to the exemplary embodiments of the present disclosure, examples of which are illustrated in the accompanying drawings. Wherever possible, the same reference numbers will be used throughout the drawings to refer to the same or like parts. In the specification, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the specification should be understood as follows.

In the present specification, where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween. Also, if a first element is described as positioned “on” a second element, it does not necessarily mean that the first element is positioned above the second element in the figure. The upper part and the lower part of an object concerned may be changed depending on the orientation of the object. Consequently, where a first element is described as positioned “on” a second element, the first element may be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous may be included unless a more limiting term, such as “just,” “immediate(ly),” or “direct(ly),” is used.

It will be understood that, although the terms “first,” “second,” and the like may be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) may be used. These terms are used merely to distinguish one element from another, and not to define a particular nature, order, sequence, or number of the elements. Where an element is described as being “linked,” “coupled,” or “connected” to another element, that element may be directly or indirectly connected to that other element unless otherwise specified. It is to be understood that additional element or elements may be “interposed” between the two elements that are described as “linked,” “connected,” or “coupled” to each other.

To elaborate, as used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Hereinafter, an example of a display apparatus according to the present disclosure will be described in detail with reference to the attached drawings. Wherever possible, the same reference numbers will be used throughout the drawings to refer to the same or like parts.

Hereinafter, referring to figures, the present disclosure will be explained. FIG. 1 is a diagram illustrating a schematic structure of a light emitting display device according to the present disclosure. In FIG. 1, X-axis refers to the direction parallel to the scan line, Y-axis refers to the direction of the data line, and Z-axis refers to the height direction of the display device.

Referring to FIG. 1, the light emitting display device comprises a substrate 110, a gate (or scan) driver 200, a pad portion 300, a source driving IC (Integrated Circuit) 410, a flexible circuit film 430, a circuit board 450, and a timing controller 500.

The substrate 110 may include an electrical insulating material or a flexible material. The substrate 110 may be made of a glass, a metal or a plastic, but it is not limited thereto. When the light emitting display device is a flexible display, the substrate 110 may be made of the flexible material such as plastic. For example, the substrate 110 may include a transparent polyimide material.

The substrate 110 may include a display area AA and a non-display area NDA. The display area AA, which is an area for displaying the video images, may be defined as the majority middle area of the substrate 110, but it is not limited thereto. In the display area AA, a plurality of scan lines (or gate lines), a plurality of data lines and a plurality of unit pixels UP may be formed or disposed. The unit pixels UP are arrayed in a matrix manner. Each of unit pixels UP may include a plurality of pixels P. Each of pixels P includes the scan line and the data line, respectively.

The non-display area NDA, which is an area not displaying the video images, may be defined at the circumference areas of the substrate 110 surrounding all or some of the display area AA. In the non-display area NDA, the gate driver 200 and the pad portion 300 may be formed or disposed.

The gate driver 200 may supply the scan (or gate) signals to the scan lines according to the gate control signal input through the pad portion 300 from the timing controller 500. The gate driver 200 may be formed at the non-display area NDA at any one outside of the display area AA on the substrate 110, as a GIP (Gate driver In Panel) type. GIP type means that the gate driver 200 is directly formed on the substrate 110. For example, the gate driver 200 may be configured as a shift register, and the GIP type refers to a structure in which transistors for the shift resistor of the gate driver 200 are directly formed on the substrate 110.

The pad portion 300 may supply data signals to data lines according to a data control signal input from the timing controller 500. The pad portion 300 may be formed as a driving chip and mounted the flexible circuit film 430. The flexible circuit film 430 may be attached to the non-display area NDA of one edge of the display area AA of the substrate 110.

The source driving IC 410 may receive the digital video data and the source control signal from the timing controller 500. The source driving IC 410 may convert the digital video data into the analog data voltages according to the source control signal and then supply that to the data lines. When the source driving IC 410 is made as a chip type, it may be installed on the flexible circuit film 430 as a COF (chip on film) or COP (chip on plastic) type.

The flexible circuit film 430 may include a plurality of first link lines connecting the pad portion 300 to the source driving IC 410, and a plurality of second link lines connecting the pad portion 300 to the circuit board 450. The flexible circuit film 430 may be attached on the pad portion 300 using an anisotropic conducting film, so that the pad portion 300 may be connected to the first link lines of the flexible circuit film 430.

The circuit board 450 may be attached to the flexible circuit film 430. The circuit board 450 may include a plurality of circuits implemented as the driving chips. For example, the circuit board 450 may be a printed circuit board or a flexible printed circuit board. The circuit board 450 may be a printed circuit board or a flexible printed circuit board.

The timing controller 500 may receive the digital video data and the timing signal from an external system board through the line cables of the circuit board 450. The timing controller 500 may generate a gate control signal for controlling the operation timing of the gate driver 200 and a source control signal for controlling the source driving IC 410, based on the timing signal. The timing controller 500 may supply the gate control signal to the gate driver 200 and supply the source control signal to the source driving IC 410. Depending on the product types, the timing controller 500 may be formed as one chip with the source driving IC 410 and mounted on the substrate 110.

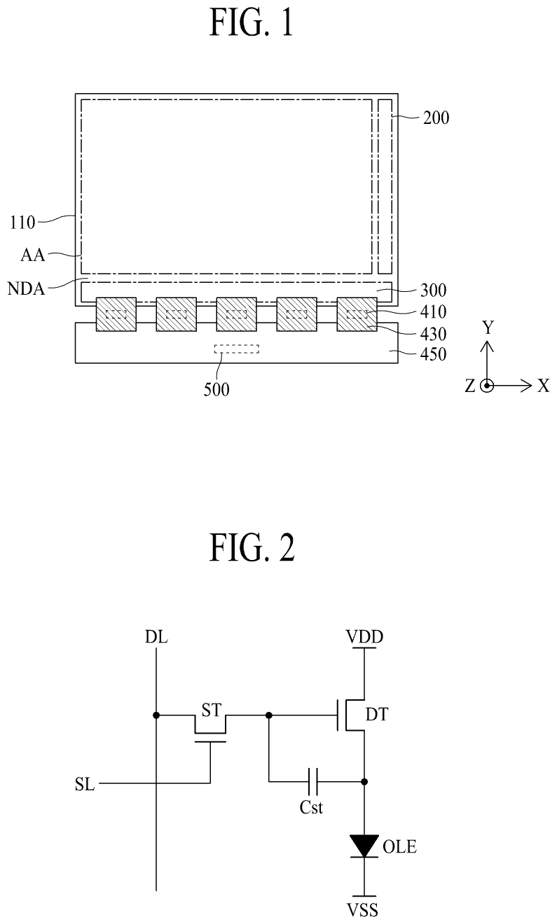

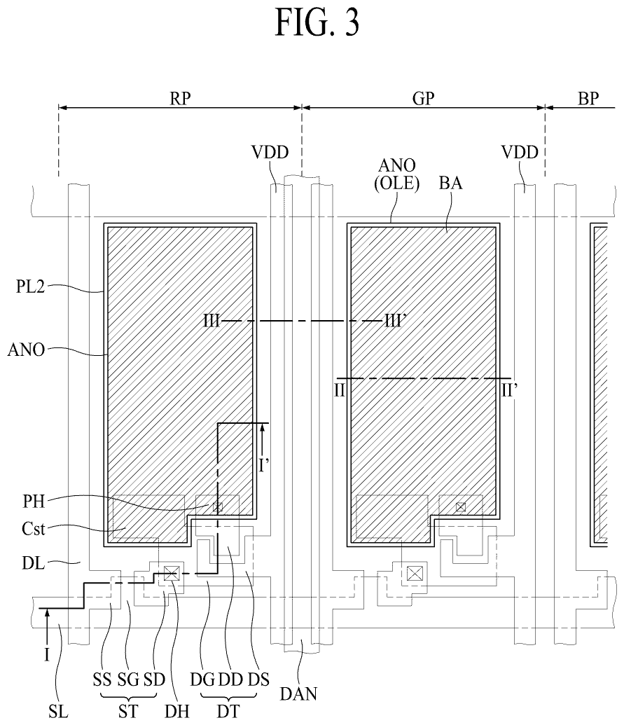

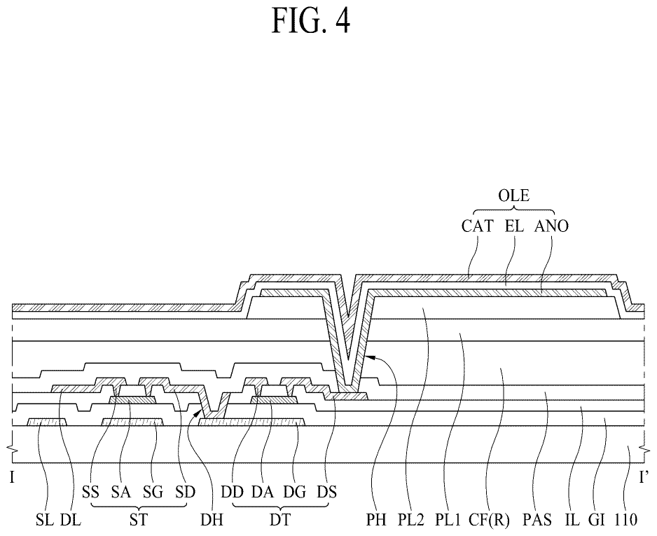

Hereinafter, referring to FIGS. 2 to 4, a preferred embodiment of the present disclosure will be explained. FIG. 2 is a circuit diagram illustrating a structure of one pixel included in the light emitting display device according to an example of the present disclosure. FIG. 3 is a plan view illustrating an arrangement structure of the pixels disposed in the light emitting display device according to an example of the present disclosure. FIG. 4 is an enlarged cross-sectional view taken along line I-I′ in FIG. 3, for illustrating the structure of a light emitting display device according to an example of the present disclosure.

One pixel of the light emitting display device may be defined by a scan line SL, a data line DL and a driving current line VDD. In any one pixel of the light emitting display device may include a switching thin film transistor ST, a driving thin film transistor DT, a light emitting diode OLE, and a capacitance Cst. The driving current line VDD may be supplied with a high-level voltage for driving the light emitting diode OLE.

For example, the switching thin film transistor ST may be disposed at a location where the scan line SL and the data line DL intersect. The switching thin film transistor ST may include a gate electrode SG, a semiconductor layer SA, a source electrode SS and a drain electrode SD. The gate electrode SG may be connected to the scan line SL. The source electrode SS may be connected to the data line DL, and the drain electrode SD may be connected to the driving thin film transistor DT. The semiconductor layer SA may be disposed on a gate insulating layer GI as overlapping with the gate electrode SG. The portion of the semiconductor layer SA overlapping the gate electrode SG may be defined as a channel region.

An intermediate insulating layer IL may be deposited on the semiconductor layer SA. The source electrode SS and the drain electrode SD may be formed on the intermediate insulating layer IL. The source electrode SS may be connected to one side of the semiconductor layer SA via one contact hole formed at the intermediate insulating layer IL. The drain electrode SD may be connected to another side of the semiconductor layer SA via another contact hole formed at the intermediate insulating layer IL. The switching thin film transistor ST may select a pixel P to be driven by applying a data signal to the driving thin film transistor DT.

The driving thin film transistor DT may drive the light emitting diode OLE of the pixel selected by the switching thin film transistor ST. The driving thin film transistor DT may include a gate electrode DG, a semiconductor layer DA, a source electrode DS and a drain electrode DD. The gate electrode DG of the driving thin film transistor DT may be connected to the drain electrode SD of the switching thin film transistor ST. For example, the gate electrode DG of the driving thin film transistor DT may be connected to the drain electrode SD of the switching thin film transistor ST via a drain contact hole DH penetrating the gate insulating layer GI covering the gate electrode DG. The drain electrode DD may be connected to the driving current line VDD, and the source electrode DS may be connected to an anode electrode ANO of the light emitting diode OLE. The capacitance Cst may be disposed between the gate electrode DG of the driving thin film transistor DT and the anode electrode ANO of the light emitting diode OLE.

The intermediate insulating layer IL may be deposited on the semiconductor layer DA. The source electrode DS and the drain electrode DD may be formed on the intermediate insulating layer IL. The source electrode DS may be connected to one side of the semiconductor layer DA via one contact hole formed at the intermediate insulating layer IL. The drain electrode DD may be connected to another side of the semiconductor layer DA via another contact hole formed at the intermediate insulating layer IL.

The driving thin film transistor DT may be disposed between the driving current line VDD and the light emitting diode OLE. The driving thin film transistor DT may control the amount of current flowing from the driving current line VDD to the light emitting diode OLE according to the magnitude of the voltage of the gate electrode DG connected to the drain electrode SD of the switching thin film transistor ST.

The light emitting diode OLE may include an anode electrode ANO, an emission layer EL and a cathode electrode CAT. The light emitting diode OLE may emit lights in response to an electric current controlled by the driving thin film transistor DT. In detail, since the amount of light emitted may be adjusted according to the current controlled by the driving thin film transistor DT, the brightness of the light emitting display device may be controlled. The anode electrode ANO of the light emitting diode OLE may be connected to the source electrode DS of the driving thin film transistor DT, and the cathode electrode CAT may be connected to a low voltage line VSS to which a low potential voltage is applied. The light emitting diode OLE may be driven by the difference between a low-potential voltage and a high-potential voltage controlled by a driving thin film transistor DT.

A passivation layer PAS is deposited on the surface of the substrate 110 having the thin film transistors ST and DT. The passivation layer PAS may include an inorganic material such as silicon oxide (SiOx) or silicon nitride (SiNx). The layered structure from the gate electrodes SG and DG and scan line SL to the passivation layer PAS deposited on the substrate 110 may be called as a ‘driving element layer.’ The driving element layer may include thin film transistors for driving light emitting diodes OLE included in a ‘light emitting element layer’ formed on the driving element layer.

A color filter CF may be formed on the passivation layer PAS. The color filter CF may be disposed on each pixel P. For example, the color filter CF may include any one of red color, blue color and green color at each pixel. For another example, the color filter CF may include any one of red color, blue color, green color and white color at each pixel.

A first planarization layer PL1 may be deposited on the color filter CF. The first planarization layer PL1 may be a thin film for making the surface of the substrate 110 on which thin film transistors ST and DT are formed flat. To make even the height difference, the first planarization layer PL1 may be formed of an organic material.

A second planarization layer PL2 may be formed on the first planarization layer PL1. The second planarization layer PL2 may have the same shape as the anode electrode ANO and slightly larger size than the anode electrode ANO. For example, the second planarization layer PL2 may be disposed so as not to overlap with the scan line SL, the data line DL and the driving current line VDD. The first planarization layer PL1 may be deposited as covering entire top surface of the substrate 110. The second planarization layer PL2 may be patterned to have an isolated island shape, one for each pixel.

A pixel contact hole PH for exposing a portion of the source electrode DS of the driving thin film transistor DT may be formed as penetrating the passivation layer PAS, the color filter CF, the first planarization layer PL1 and the second planarization layer PL2. An anode electrode ANO may be formed on the second planarization layer PL2. The anode electrode ANO may be connected to the source electrode DS of the driving thin film transistor DT via the pixel contact hole PH. In the drawing, some portions of the second planarization layer PL2 is overlapped with the driving thin film transistor DT, the pixel contact hole PH and the capacitance Cst. However, it is not limited thereto, the second planarization layer PL2 may not be overlapped with the driving thin film transistor DT, the pixel contact hole PH and the capacitance Cst.

The anode electrode ANO may have different material depending on the emission type of the light emitting diode OLE. For the bottom emission type in which the light emitting diode OLE emits toward the substrate 110, the anode electrode ANO may be formed of a transparent conductive material. For the top emission type in which the light emitting diode OLE emits upward opposing the substrate 110, the anode electrode ANO may be formed of a metal material having excellent light reflectance. In this case, the anode electrode ANO may have a structure in which a transparent conductive layer and a metal layer are stacked.

For the bottom emission type, the anode electrode ANO may be made of a transparent conductive material (TCO) or semi-transparent conductive material. For instance, the anode electrode ANO may be made of a transparent conductive material such as indium tin oxide (ITO), indium zinc oxide (IZO) or indium zinc tin oxide (IZTO). Otherwise, the anode electrode ANO may be made of a semi-transparent layer of magnesium (Mg), silver (Ag) or an alloy of magnesium (Mg) and silver (Ag) with a thickness of less than 100 nm. The anode electrode ANO may be called as a first electrode or a transparent electrode.

An emission layer EL may be deposited on the anode electrode ANO. The emission layer EL may be disposed on the entire surface of the substrate 110 as one sheet type covering continuously the upper surface of the substrate 110. A cathode electrode CAT may deposited on the emission layer EL. The cathode electrode CAT may be disposed as a thin layer continuously deposited on the entire surface of the substrate 110. The stacked structure of the anode electrode ANO, the emission layer EL and the cathode electrode CAT may configure the light emitting diode OLE.

The cathode electrode CAT may be made of a metal material having excellent light reflectance. For example, the cathode electrode CAT may be formed of a metal material with excellent light reflectance with a thickness of at least 2,000 Å to 3,000 Å (200 nm to 300 nm). Here, the metal material having excellent light reflectance may include aluminum (Al), magnesium (Mg), calcium (Ca), silver (Ag) or alloy of them (i.e., aluminum-magnesium alloy (AlMg)) For another example, the cathode electrode CAT may include thin metal layer having high reflectance such as stack of aluminum and titanium (Ti/Al/Ti), stack of aluminum and indium tin oxide (ITO/Al/ITO), silver alloy, or stack of silver alloy and indium tin oxide (ITO/Ag alloy/ITO). Here, silver alloy may be an alloy of silver (Ag), palladium (Pd) and copper (Cu). The cathode electrode CAT may be called as a second electrode, reflection electrode, or counter electrode.

The stacked structure of the anode electrode ANO, the emission layer EL and the cathode electrode CAT may configure the light emitting diode OLE. The light emitting display device according to the present disclosure may have a structure in which each of light emitting diode OLE is disposed on the second planarization layer PL2 patterned with protruding island shape within the pixel P.

The layers from the color filter CF disposed on the passivation layer PAS to the cathode electrode CAT may be called as a ‘light emitting element layer.’

In detail, within each pixel P, the second planarization layer PL2 may be formed as an island shape with a predetermined thickness, and the anode electrode ANO may be formed within the top surface of the second planarization layer PL2. The emission layer EL may be deposited to cover the upper surface of the first planarization layer PL1, the etched sidewall of the second planarization layer PL2, the edge portion of the top surface of the second planarization layer PL2, and the top surface of the anode electrode ANO. The cathode electrode CAT may be also deposited with the same profile as the emission layer EL. As a result, the cathode electrode CAT may have a cap, ‘∩,’ shape facing downward. Since the cathode electrode CAT may be made of a metal material with excellent light reflectance, the cathode electrode CAT may have a structure in which the cap shaped micro mirrors are formed around the planarization layer PL.

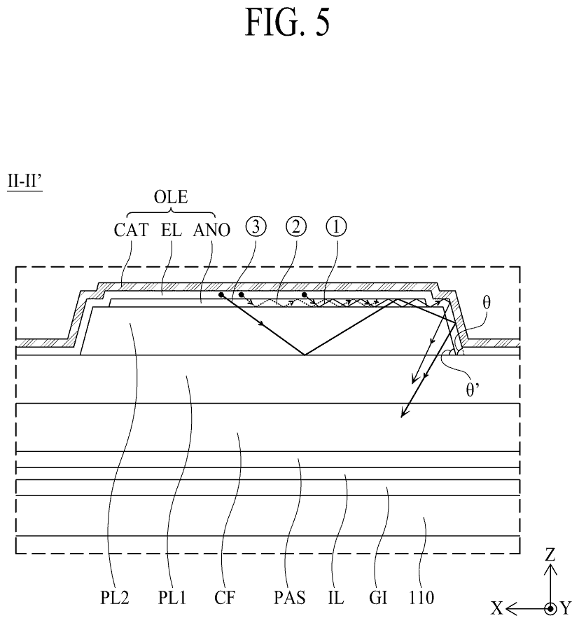

In the case of the bottom emission type, there may be a disadvantage in that the area ratio of the aperture area to the pixel area may be relatively smaller than top emission type, due to the thin film transistor ST and DT, capacitance Cst, the scan line SL, the data line DL and the driving current line VDD. The light emitting display device according to the present disclosure may provide a structure equipped with a micro mirror so that light generated from the emission layer may be provided toward the substrate 110 placed underneath without loss even though the aperture area is small. Hereinafter, referring to FIG. 5, the mechanism for enhancing the light extraction efficiency by the micro mirror will be explained. FIG. 5 is an enlarged cross-sectional view taken along line II-II′ in FIG. 3, for illustrating light paths in a light emitting display device according to an example of the present disclosure.

Referring to FIG. 5, it will be explained that the optical path \textcircled{1} for light emitted from the emission layer EL at the edge region of the anode electrode ANO. Lights emitted from the emission layer EL may be transmitted as a spherical wave. Lights may be emitted in all directions 360 degrees on the cross-sectional view. Among the lights, the light emitted to the top direction may be reflected by the cathode electrode CAT and travel downward. That is, most of all lights generated from the emission layer EL may be radiated in a 180-degree downward direction. These lights may be incident into the anode electrode ANO. Since the anode electrode ANO is made of a transparent conductive material, 60% to 70% of the lights may pass through the anode electrode ANO, pass through the color filter CF placed underneath, and be emitted outside the substrate 110.

Further, the anode electrode ANO may be a transparent conductive material with a refractive index of 2.0 to 2.3. The upper surface of the anode electrode ANO is in contact with the emission layer EL, and the bottom surface is in contact with the planarization layer PL. The emission layer EL and the planarization layer PL may have a refractive index of 1.3 to 1.5. As a result, a structure may be formed in which an anode electrode ANO with a high refractive index is interposed between two low refractive layers. Therefore, among the lights incident into the anode electrode ANO, 30% to 40% corresponding to the total reflection condition may be propagated in the horizontal direction (X-axis direction) inside the anode electrode ANO.

According to the material of the emission layer EL, the refractive index of the emission layer EL may be similar to the refractive index of the anode electrode ANO. In this case, among the lights emitted from the emission layer EL, the lights totally reflected at the interface between the anode electrode ANO and the planarization layer PL may be trapped between the cathode electrode CAT and the planarization layer PL, so these lights may propagate in the horizontal direction (X-axis direction).

Lights propagating horizontally within the anode electrode ANO, or between the cathode electrode CAT and the planarization layer PL may be emitted from the end of the anode electrode ANO and be reflected by the cathode electrode CAT having the micro mirror structure to go downward. When there is no micro mirror structure formed by the protrusion of the planarization layer PL, the lights may be propagated horizontally and extinguished. However, according to this structure, the lights can be extracted downward by the micro mirror, thereby improving the light extraction efficiency.

Here, in order to ensure that the lights reflected by the cathode electrode CAT having a micro mirror structure may be emitted to the downward direction properly, it is necessary to adjust the angle of the inclination of the cathode electrode CAT deposited on the etched sidewall where the step of the planarization layer PL is formed. For example, the angle θ of the inclined surface of the cathode electrode CAT with respect to the horizontal surface of the substrate 110 may preferably be in the range of 40 degree to 80 degree. More preferably, the inclination angle θ may be in the range of 50 degree to 75 degree. Since the cathode electrode CAT is deposited along the step shape formed between the first planarization layer PL1 and the second planarization layer PL2, the inclination angle θ of the cathode electrode CAT may be substantially equal to the side wall inclination angle θ′ of the second planarization layer PL2 protruded on the first planarization layer PL1. Therefore, it is preferable to form the inclination angle θ′ between the top surface of the first planarization layer PL1 and the sidewall of the second planarization layer PL2 to be 50 degree to 75 degree.

Next, it is explained about the optical path \textcircled{2} for light emitted from the emission layer EL at the central region of the anode electrode ANO. Lights generated from the emission layer EL may be radiated 180 degree downward by the same mechanism as described above. Since the anode electrode ANO is made of a transparent conductive material, 60% to 70% of the lights may pass through the anode electrode ANO, pass through the color filter CF placed underneath, and then be emitted outside the substrate 110.

However, among the lights incident into the anode electrode ANO, 30% to 40% of the lights that meet the total reflection condition may be propagated in the horizontal direction (X-axis direction) inside the anode electrode ANO. In particular, the lights generated at the central region of the pixel may undergo a total reflection process inside the anode electrode ANO, so that the length of the propagating optical path \textcircled{2} is longer than the length of the optical path \textcircled{1} described above. Therefore, it may be dissipated as heat energy inside the anode electrode ANO before being emitted through the end of the anode electrode ANO. In general, when lights propagate over a length of 20 μm or more inside the anode electrode ANO, the lights may be extinguished or annihilated.

The present disclosure may propose a structural feature for minimizing the amount of light lost due to total reflection within an anode electrode ANO. For example, the present disclosure may be characterized in which the second planarization layer PL2 in contact with the anode electrode ANO uses a transparent organic material having a refractive index which is the same as or about 0.2 lower than the refractive index of the anode electrode ANO.

With this feature, light generated from the emission layer EL may be emitted in the same manner as optical path \textcircled{3}. Lights generated from the emission layer EL may be radiated 180 degree downward by the same mechanism as described above. Since the anode electrode ANO may be made of a transparent conductive material and the second planarization layer PL2 may have a refractive index similar to that of the anode electrode ANO, 90% to 98% of lights may transmit through the anode electrode ANO and the second planarization layer PL2. Since the first planarization layer PL1 may have a refractive index of 1.4 to 1.5, 60% to 70% of the light incident into the second planarization layer PL2 may pass through the first planarization layer PL1, pass through the color filter CF arranged underneath, and be emitted outside the substrate 110.

However, among the light incident into the second planarization layer PL2, about 30% to 40% of the light that satisfies the total reflection condition at the interface with the first planarization layer PL1 may be re-incident into the anode electrode ANO and be totally reflected again on the upper surface of the anode electrode ANO. That is, these lights may propagate in the horizontal direction (X-axis direction) inside the anode electrode ANO and the second planarization layer PL2.

The lights following the optical path \textcircled{3} may be reflected within a total reflection space including the second planarization layer PL2 having thickness of 1 μm to 1.5 μm which is wider than the total reflection space for optical paths \textcircled{1} and \textcircled{2}, the number of total reflections may be significantly reduced. As a result, lights emitted from the central area of the pixel and totally reflected may also reflected by the cathode electrode CAT having a micro mirror structure, and then emitted downward.

The light emitting display device according to the present disclosure may improve the light extraction efficiency by extracting lights generated from the emission layer EL by the second planarization layer PL2 protruding in an island shape and the cathode electrode CAT having a micro mirror structure due to the step shape of the planarization layer PL. In particular, the second planarization layer PL2 may have a refractive index that is the same as or slightly lower than that of the anode electrode ANO, and the first planarization layer PL1 disposed under the second planarization layer PL2 may be configured to have a low refractive index. Thereby, lights which would otherwise be lost due to total reflection may be extracted to the outside of the substrate, so that the light extraction efficiency may be further improved.

For example, the anode electrode ANO may have a refractive index of 2.0 to 2.3. The second planarization layer PL2 may have a refractive index of 1.8 to 2.0, which is the same as or about 0.2 or less different from the anode electrode ANO. Meanwhile, the first planarization layer PL1 may have a refractive index of 1.3 to 1.5, which is 0.5 or more lower than that of the second planarization layer PL2.

The structural features of each pixel in the light emitting display device according to the present disclosure have been explained above. Hereinafter, the structural features for eliminating the lateral leakage current between neighboring pixels may be explained. There may be various structural features for eliminating the lateral leakage current, so various embodiments may be described.

### First Embodiment

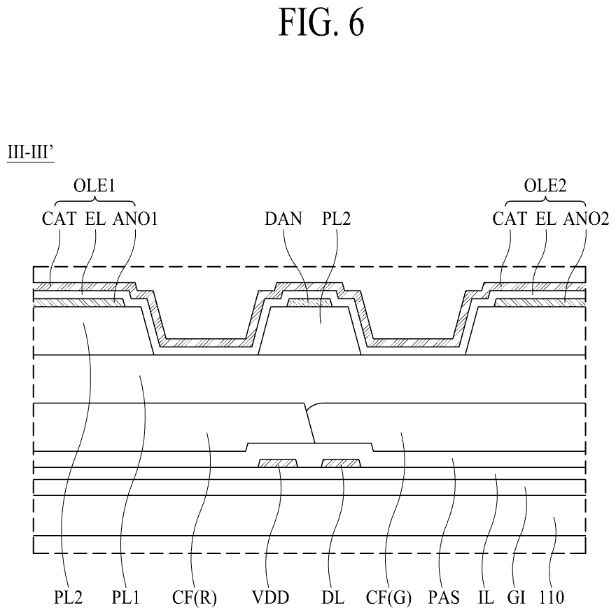

Hereinafter, referring to FIG. 6, a structure of a light emitting display device according to a first embodiment of the present disclosure will be described. FIG. 6 is an enlarged cross-sectional view, taken along line II-II′ of FIG. 3, illustrating light paths in a light emitting display device according to a first embodiment of the present disclosure.

The light emitting display device according to the present disclosure may have a structure in which a second planarization layer PL2 having high refractive index is stacked on a first planarization layer PL1 having low refractive index. In particular, the second planarization layer PL2 may be patterned in an island shape, and the cathode electrode CAT may cover the top surface and the side walls of the second planarization layer PL2, so a micro mirror structure is formed. Further, the interface between the first planarization layer PL1 and the second planarization layer PL2 may be configured so that total reflection occurs at the interface, and the totally reflected lights may be reflected by the cathode electrode CAT and emitted downward.

In this structure, the etched sidewall of the second planarization layer PL2 may have a slope angle of 50 degree to 70 degree. The emission layer EL may have a structure that is continuously connected between two neighboring pixels. For example, with a structure where a first light emitting diode OLE1 arranged in a first pixel and a second light emitting diode OLE2 arranged in a second pixel may be adjacent to each other, the emission layer EL may have a coated structure continuously spread from the first light emitting diode OLE1 to the second light emitting diode OLE2. Since the etched sidewall of the second planarization layer PL2 may have a relatively gentle slope angle, the emission layer EL may be continuously deposited from the first light emitting diode OLE1 to the second light emitting diode OLE2 with a uniform thickness.

Accordingly, leakage current may flow laterally along the emission layer EL, i.e., in the X-axis direction, which may cause problems of switching on the light emitting diode OLE of unwanted pixels. The first embodiment of the present disclosure may provide a structure for preventing problems due to the lateral leakage currents.

Referring to FIG. 6, a second planarization layer PL2 with an island shape may be further disposed between the first light emitting diode OLE1 and the second light emitting diode OLE2. Further, a dummy anode electrode DAN with an island shape may be disposed on the top surface of the second planarization layer PL2.

With a configuration shown in FIG. 6, the emission layer EL may have longer path length due to the structure in which an element disposed between the first light emitting diode OLE1 and the second light emitting diode OLE2. As a result, the path for the lateral leakage current from the first light emitting diode OLE1 to the second light emitting diode OLE2 may be also elongated, so that the lateral leakage current may be suppressed to flow to the neighboring pixels.

However, with condition where the slope angle of the sidewall of the second planarization layer PL2 is as gentle as 50 degree, the lateral leakage current may not be completely suppressed. In particular, in the case of light emitting display device configured with an ultra-high pixel density of 400 PPI (pixel per inch) or higher, or of the light emitting display device configured with small size such as 10 inches or less of diagonal length, the gap between pixels may become narrow, so that the lateral leakage current may be easily occurred.

Hereinafter, various embodiments of the light emitting display devices having structures that may additionally prevent problems which may occur in the first embodiment will be explained.

### Second Embodiment

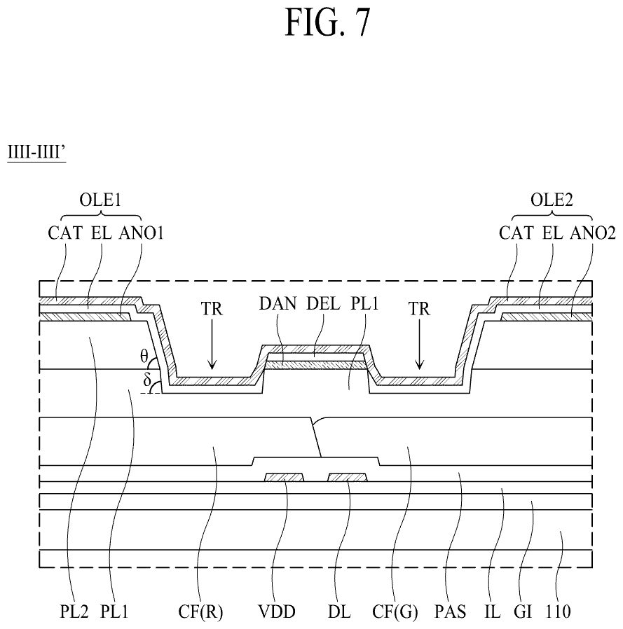

Hereinafter, referring to FIG. 7, a structure of a light emitting display device according to the second embodiment of the present disclosure will be explained. FIG. 7 is an enlarged cross-sectional view, taken along line II-II′ of FIG. 3, illustrating a structure of a light emitting display device according to a second embodiment of the present disclosure.

Referring to FIG. 7, a first light emitting diode OLE1 and a second light emitting diode OLE2 may be arranged adjacent to each other. The second planarization layer PL2 may have a structure in which some portions of the second planarization layer PL2 between the first emitting diode OLE1 and the second light emitting diode OLE2 may be completely removed so that the first planarization layer PL1 may be exposed. Further, the first planarization layer PL1 may be etched with certain depth to form a trench TR.

A dummy anode electrode DAN may be formed on a first planarization layer PL1 exposed between the first light emitting diode OLE1 and the second light emitting diode OLE2. The dummy anode electrode DAN may be physically and electrically disconnected from the first anode electrode ANO1 and the second anode electrode ANO2. As seeing on a plan view of the light emitting display device, the dummy anode electrode DAN may be disposed between two neighboring pixel columns, and may have a segment shape extending along Y-axis. In some cases, the dummy anode electrode DAN may be used as a line for supplying an electric signal different from the anode electrode ANO.

The first anode electrode ANO1 of the first light emitting diode OLE1 and the second anode electrode ANO2 of the second light emitting diode OLE2 may be disposed on the top surface of the second planarization layer PL2. Meanwhile, the dummy anode electrode DAN may be disposed on the top surface of the first planarization layer PL1 exposed between the first light emitting diode OLE1 and the second light emitting diode OLE2. Using the first anode electrode ANO1, the second anode electrode ANO1 and the dummy anode electrode DAN as a mask, the first planarization layer PL1 may be patterned to form a trench TR having a predetermined depth. Since the second planarization layer PL2 may be a different material from the first planarization layer PL1, the second planarization layer PL2 may not be etched when the first planarization layer PL1 is patterned, and the etched sidewall may not be over etched to be a slope angle larger than 70 degree. Therefore, problems such as pixel shrinkage may not occur.

By over-etching the first planarization layer PL1, the angle δ of the sidewall of the trench TR may be formed to have a steep slope angle of 70 degree or more. That is, the slope angle of the etched sidewall of the second planarization layer PL2 may have an angle in range of 50 degree to 70 degree, relatively gentle slope angle. Meanwhile, the slope angle δ of the etched sidewall formed at by patterning the trench TR in the first planarization layer PL1 may have one angle in range of 70 degree to 90 degree, relatively steep slope angle.

As a result, the emission layer EL deposited on the top surface of the substrate 110 having the trench TR may be disconnected by the trench TR. Since leakage current may not be transmitted to light emitting diodes arranged in laterally adjacent neighboring pixels along the emission layer EL, defective operation of the pixels may be prevented. The emission layer EL may be formed on each of the first light emitting diode OLE1 and the second light emitting diode OLE2, and a dummy emission layer DEL may be deposited on the dummy anode electrode DAN which is disconnected from the emission layer EL.

A cathode electrode CAT may be deposited on the emission layer EL and the dummy emission layer DEL. The cathode electrode CAT may be an inorganic metal material. Therefore, the cathode electrode CAT may be deposited as maintaining the connectivity at the portion where the emission layer EL is disconnected.

A light emitting display device according to the second embodiment of the present disclosure may have the micro mirror structure by forming the second planarization layer PL2 in an island shape, so the light extraction efficiency may be increased by extracting lights that would otherwise be lost inside the anode electrode ANO to the outside. In addition, by blocking the lateral leakage current due to the trench TR disposed between pixels, the defective operation of the pixel may be prevented, and the color purity may be enhanced.

The light emitting display device according to the second embodiment may have two trenches between the first anode electrode ANO1 of the first light emitting diode OLE1 and the second anode electrode ANO2 of the second light emitting diode OLE2. The dummy anode electrode DAN may be disposed, between two trenches TR, on the top surface of the first planarization layer PL1 placed at higher height than the bottom of the trench TR. Therefore, one trench TR may be disposed between the dummy anode electrode DAN and the first anode electrode ANO1. Further, another trench TR may be disposed between the dummy anode electrode DAN and the second anode electrode ANO2.

### Third Embodiment

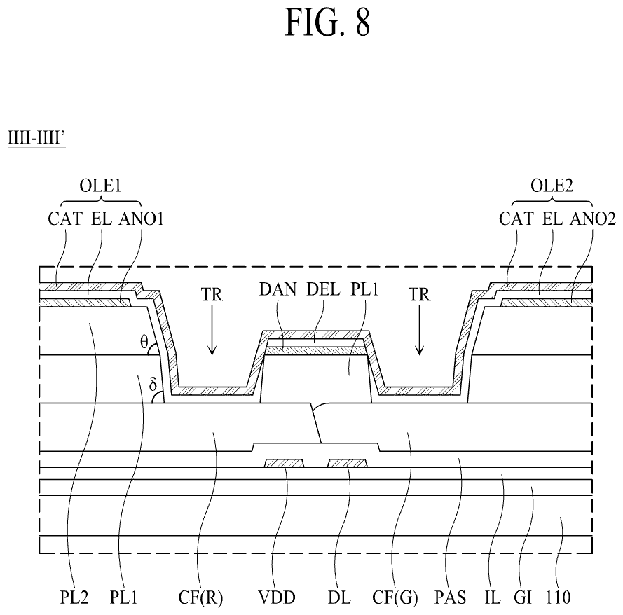

Hereinafter, referring to FIG. 8, a light emitting display device according to the third embodiment of the present disclosure will be explained. FIG. 8 is an enlarged cross-sectional view, taken along line II-II′ of FIG. 3, illustrating a structure of a light emitting display device according to a third embodiment of the present disclosure.

Referring to FIG. 8, the structure of the light emitting display device according to a third embodiment may be very similar to that of the second embodiment. The different feature of the third embodiment may be that the depth of the trench TR may be same with the thickness of the first planarization layer PL1. That is, the trench TR may be formed by completely removing the portions of the first planarization layer PL1 exposed between the dummy anode electrode DAN and the second planarization layer PL2.

The first anode electrode ANO1 of the first light emitting diode OLE1 and the second anode electrode ANO2 of the second light emitting diode OLE2 may be disposed on the top surface of the second planarization layer PL2. The dummy anode electrode DAN may be disposed on the top surface of the first planarization layer PL1 exposed between the first light emitting diode OLE1 and the second light emitting diode OLE2. Using the first anode electrode ANO1, the second anode electrode ANO2 and the dummy anode electrode DAN as a mask, the exposed portions of the first planarization layer PL1 may be completely removed, so that a trench TR having a depth corresponding to the thickness of the first planarization layer PL1 may be formed. Since the second planarization layer PL2 may be made of different material from the first planarization layer PL1, when forming the trench TR by patterning the first planarization layer PL1, the second planarization layer PL2 may not be etched. Therefore, the slope angle, i.e., 70 degree, of the sidewall of the second planarization layer PL2 may not be changed. As a result, there are no issues such as pixel shrinkage.

By forming the depth of the trench TR deep in this way, an over-etching process may be performed that increase the etching time for forming the first planarization layer PL1. Accordingly, the angle of the sidewall of the trench TR, i.e., the slope angle of the etched sidewall of the first planarization layer PL1, may be formed to have a steep angle larger than 70 degree. As a result, the emission layer EL deposited on the substrate 110 in which the trench TR is formed may be disconnected by the trench TR. Therefore, leakage current may not be transmitted to the light emitting diodes arranged in the laterally adjacent neighboring pixels along the emission layer EL, so the defective operation of the pixels due to the lateral leakage current may be prevented. The emission layer EL may be formed on each of the first light emitting diode OLE1 and the second light emitting diode OLE2. Further, a dummy emission layer DEL with disconnected connection with the light emitting diodes OLE1 and OLE2 may be deposited on the dummy anode electrode DAN.

A cathode electrode CAT may be deposited on the emission layer EL and the dummy emission layer DEL. The cathode electrode CAT may include an inorganic metal material. Therefore, the cathode electrode CAT may be deposited as maintaining the connectivity even in the portions where the connection of the emission layer EL is disconnected.

A light emitting display device according to the third embodiment of the present disclosure may have the micro mirror structure by forming the second planarization layer PL2 in an island shape, so the light extraction efficiency may be increased by extracting lights that would otherwise be lost inside the anode electrode ANO to the outside. In addition, by blocking the lateral leakage current due to the trench TR disposed between pixels, the defective operation of the pixel may be prevented and the color purity may be enhanced.

### Fourth Embodiment

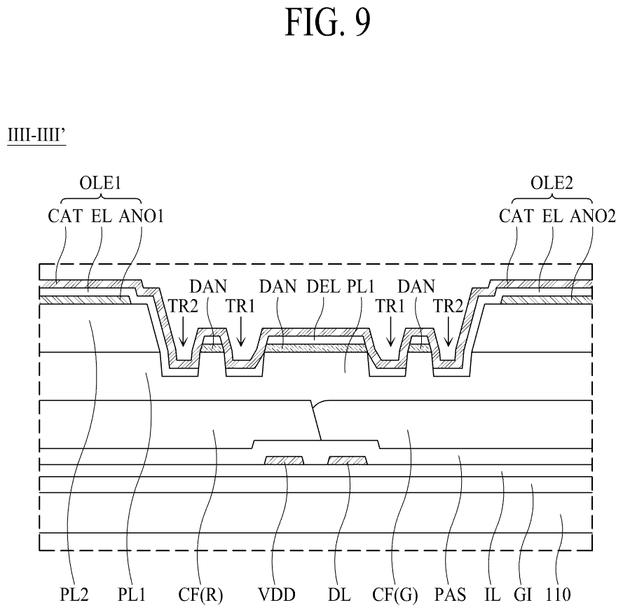

Hereinafter, referring to FIG. 9, a light emitting display device according to the fourth embodiment of the present disclosure will be explained. FIG. 9 is an enlarged cross-sectional view, taken along line II-II′ of FIG. 3, illustrating a structure of a light emitting display device according to the fourth embodiment of the present disclosure.

Referring to FIG. 9, the structure of the light emitting display device according to a fourth embodiment may be very similar to that of the second embodiment. The different feature of the fourth embodiment may be that there are two trenches TR. The trench TR may include a first trench TR1 and a second trench TR2 sequentially disposed between the dummy anode electrode DAN and the anode electrode ANO. Two trenches TR1 and TR2 may be arranged on each side of the dummy anode electrode ANO. Further, the dummy anode electrode DAN may be disposed between the first trench TR1 and the second trench TR2.

The light emitting display device according to the fourth embodiment may include 4 trenches between the first anode electrode ANO1 of the first light emitting diode OLE1 and the second anode electrode ANO2 of the second light emitting diode OLE2. Between each of the trenches TR, dummy anode electrodes DAN may be disposed on the top surface of the first planarization layer PL1 located at the height higher than the bottom of the trenches TR.

However, it is not limited thereto, various numbers of the trenches may be disposed between two neighboring anode electrodes ANO. For example, 3, 5 or 6 trenches may be disposed between two neighboring anode electrodes ANO. In this case, a dummy anode electrode DAN may not be disposed between each of the trenches.

As the number of trenches TR increases, the path of the emission layer EL deposited thereon may become longer, and the disconnection of the emission layer EL may be more reliably formed by the trenches TR.

The structure of the fourth embodiment in which 3 or more trenches TR are disposed between two neighboring anode electrode ANO may be applied to low-resolution display devices of 100 PPI or less, where the spacing between pixels is relatively wider than high resolution display devices. Alternatively, the structure according to the fourth embodiment may be applied to a large area display device of 50 inches or more, in which the gap between pixels is relatively wider due to the large area of the display device even though it has high resolution.

A light emitting display device according to the fourth embodiment of the present disclosure may have the micro mirror structure by forming the second planarization layer PL2 in an island shape, so the light extraction efficiency may be increased by extracting lights that would otherwise be lost inside the anode electrode ANO to the outside. In addition, by blocking the lateral leakage current due to the trenches TR1 and TR2 disposed between pixels, the defective operation of the pixel may be prevented and the color purity may be enhanced.

### Fifth Embodiment

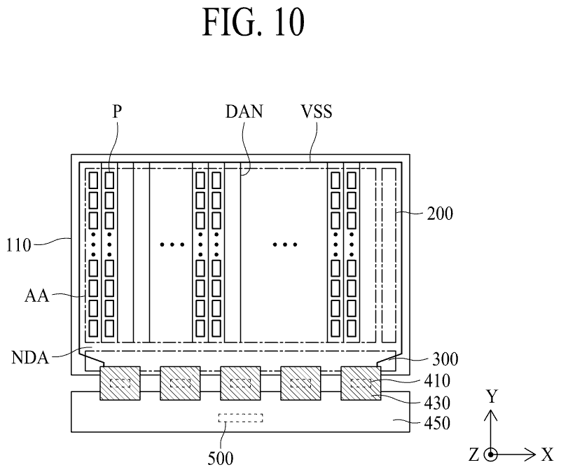

Hereinafter, referring to FIG. 10, a light emitting display device according to the fifth embodiment of the present disclosure will be explained. FIG. 10 is an enlarged plan view illustrating a structure of a light emitting display device according to a fifth embodiment of the present disclosure.

Referring to FIG. 10, a light emitting display device according to a fifth embodiment of the present disclosure may have substantially same structure with the light emitting display device shown in FIG. 1. Therefore, the descriptions for the same elements may be omitted or briefly explained, the main elements will be explained. FIG. 10 further illustrates a low-voltage line VSS, an element not shown in FIG. 1. Further, FIG. 10 illustrates a dummy anode electrode DAN, one of main elements of the light emitting display according to the present disclosure.

The low-voltage line VSS may be disposed in the non-display area NDA surrounding the display area AA. For example, the low-voltage line VSS may be placed on the left side, the upper side and the right side of the display area AA, so that the low-voltage line VSS may surround the display area AA with a shape of ‘∩.’ The low-voltage line VSS may be connected to the pad portion 300 placed on the non-display area NDA disposed at the lower side of the display area AA, and further connected to the timing controller 500 via the flexible circuit film 430. The timing controller 500 may supply a low-voltage signal to the low-voltage line VSS. The low-voltage line VSS may be connected to the pixels P arrayed in the display area AA. For example, the low-voltage line VSS may be connected to the cathode electrode CAT of the light emitting diode OLE described in FIGS. 2 to 4.

According to the first embodiment to the fourth embodiment of the present disclosure, the light emitting display device according to the present disclosure may include a dummy anode electrode DAN disposed on a second planarization layer PL2 arranged in an island shape between two adjacent pixel columns. In particular, in the second embodiment shown in FIG. 7, the dummy anode electrode DAN may be disposed between two trenches TR located between two neighboring pixel columns.

As the dummy anode electrode DAN may be disposed between two neighboring pixel columns, the dummy anode electrode DAN may have a line segment shape along vertical (Y-axis) direction in the display area AA. The dummy anode electrode DAN may be formed of the same material as the anode electrode ANO, the transparent conductive material. Therefore, the dummy anode electrode DAN may be used as an element for supplying an electric signal.

For example, by connecting the dummy anode electrode DAN to the low-voltage line VSS disposed at the upper side of the display area AA, the dummy anode electrode DAN may be used as an auxiliary low-voltage line. According to the descriptions referring to FIGS. 4 to 9, a cathode electrode CAT may be disposed on the dummy anode electrode DAN. The cathode electrode CAT is an element that receives the base (or ground) voltage for driving the light emitting diode OLE, it is necessary to always maintain a stable and constant low-potential voltage. Therefore, the dummy anode electrode DAN in surface contact with the cathode electrode CAT may be connected to the low-voltage line VSS, so that the low-voltage of the cathode electrode CAT may be always kept in constant state.

A light emitting display device according to an example of the present disclosure comprises: a substrate, a driving element layer, a first planarization layer, a second planarization layer, an anode electrode, an emission layer and a cathode electrode. The substrate includes a plurality of pixels. The driving element layer is disposed on the substrate. The first planarization layer is disposed on the driving element layer. the second planarization layer is disposed within each pixel on the first planarization layer. The anode electrode is disposed on the second planarization layer. The emission layer is disposed on the first planarization layer, the second planarization layer and the anode electrode. The cathode electrode is disposed on the emission layer.

In sum, the various embodiments of the disclosed light emitting display device enhance light extraction efficiency by incorporating micro mirror structures formed through patterned cathode electrodes over island-shaped planarization layers. These structures redirect light that would otherwise be lost due to total internal reflection, guiding it toward the substrate to improve brightness. The device also utilizes refractive index layering, with materials arranged so that light transitions from a higher index anode to lower index planarization layers, reducing optical loss and increasing emission efficiency.

To prevent lateral leakage current and improve color purity, especially in high-resolution or compact displays, the device includes trenches and dummy anode electrodes between adjacent pixels. These features interrupt the continuity of the emission layer, effectively isolating each pixel. Additionally, the sidewalls of the planarization layers are angled between 50 and 75 degrees to optimize light redirection. These structural and material arrangements result in improved display performance, pixel separation, and adaptability for advanced display applications.

In an example, the anode electrode includes at least one of a transparent conductive material and semi-transparent metal material. The cathode electrode includes an opaque metal material.

In an example, the emission layer is deposited on a top surface of the first planarization layer, a sidewall of the second planarization layer, an edge portion of a top surface of the second planarization layer and a top surface of the anode electrode. The cathode electrode is disposed in surface contact with the emission layer.

In an example, a refractive index of the second planarization layer is at most 0.2 lower than a refractive index of the anode electrode. A refractive index of the first planarization layer is at least 0.5 lower than the refractive index of the second planarization layer.

In an example, the refractive index of the anode electrode is in range of 2.0 to 2.3. The refractive index of the second planarization layer is in range of 1.8 to 2.0. The refractive index of the first planarization layer is in range of 1.3 to 1.5.

In an example, the substrate further comprises: a first pixel and a second pixel neighboring each other; a first light emitting diode disposed at the first pixel; a second light emitting diode disposed at the second pixel; and a dummy anode electrode disposed between the first light emitting diode and the second light emitting diode.

In an example, the light emitting display device further comprises: at least one trench disposed between the first light emitting diode and the second light emitting diode.

In an example, the trench is depressed or recessed from a top surface of the first planarization layer to a predetermined position inside the first planarization layer.

In an example, the trench is depressed or recessed from a top surface of the first planarization layer to a bottom surface of the first planarization layer.

In an example, the trench includes 2 to 4 trenches between the first light emitting diode and the second light emitting diode.

In an example, the emission layer is disconnected between the first light emitting diode and the second light emitting diode by the trench.

In an example, the light emitting display device further comprises: a trench depressed or recessed into the first planarization layer between the first light emitting diode and the dummy anode electrode. The first light emitting diode includes: the second planarization layer on the first planarization layer; a first anode electrode on the second planarization layer; the emission layer on the first anode electrode; and the cathode electrode on the emission layer. The second light emitting diode includes: the second planarization layer on the first planarization layer; a second anode electrode on the second planarization layer; the emission layer on the second anode electrode; and the cathode electrode on the emission layer.

In an example, the trench includes a first trench and a second trench disposed adjacently between the first light emitting diode and the dummy anode electrode.

In an example, the substrate includes: a display area including the plurality of pixels; a non-display area surrounding the display area; and a low-voltage line disposed at the non-display area. The dummy anode electrode is connected to the low-voltage line.

A light emitting display device according to another example of the present disclosure comprises: a substrate having a plurality of pixels disposed thereon; a driving element layer on the substrate; a first planarization layer on the driving element layer; a second planarization layer protruding having an island shape on the first planarization layer; an anode electrode on the second planarization layer; an emission layer on the first planarization layer, a sidewall of the second planarization layer that is not covered by the anode electrode and the anode electrode; and a cathode electrode on the emission layer, wherein the anode electrode includes a transparent conductive material, and wherein a refractive index of the second planarization layer is at most 0.2 lower than a refractive index of the anode electrode.

In an example, the emission layer is further disposed on an edge portion of a top surface of the second planarization layer that is not covered by the anode electrode.

In an example, a refractive index of the first planarization layer is at least 0.5 lower than the refractive index of the second planarization layer.

In an example, an inclination angle of the sidewall of the second planarization layer with respect to a horizontal surface is 40 to 80 degrees.

In an example, an inclination angle of the sidewall of the second planarization layer with respect to a horizontal surface is 50 to 75 degrees.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A light emitting display device comprising:
a substrate having a plurality of pixels;
a driving element layer on the substrate;
a first planarization layer on the driving element layer;
a second planarization layer within each of the plurality of pixels on the first planarization layer;
an anode electrode on the second planarization layer;
an emission layer on the first planarization layer, the second planarization layer, and the anode electrode; and
a cathode electrode on the emission layer.

2. The light emitting display device according to claim 1, wherein the anode electrode includes at least one of a transparent conductive material and semi-transparent metal material, and
wherein the cathode electrode includes an opaque metal material.

3. The light emitting display device according to claim 1, wherein the emission layer is deposited on a top surface of the first planarization layer, a sidewall of the second planarization layer, an edge portion of a top surface of the second planarization layer and a top surface of the anode electrode, and
wherein the cathode electrode is disposed in surface contact with the emission layer.

4. The light emitting display device according to claim 1, wherein a refractive index of the second planarization layer is at most 0.2 lower than a refractive index of the anode electrode, and
wherein a refractive index of the first planarization layer is at least 0.5 lower than the refractive index of the second planarization layer.

5. The light emitting display device according to claim 4, wherein the refractive index of the anode electrode is in range of 2.0 to 2.3,
wherein the refractive index of the second planarization layer is in range of 1.8 to 2.0, and
wherein the refractive index of the first planarization layer is in range of 1.3 to 1.5.

6. The light emitting display device according to claim 1, further comprising:
a first pixel and a second pixel neighboring each other;
a first light emitting diode disposed at the first pixel;
a second light emitting diode disposed at the second pixel; and
a dummy anode electrode disposed between the first light emitting diode and the second light emitting diode.

7. The light emitting display device according to claim 6, further comprising:
at least one trench disposed between the first light emitting diode and the second light emitting diode.

8. The light emitting display device according to claim 7, wherein the at least one trench is depressed from a top surface of the first planarization layer to a predetermined position inside the first planarization layer.

9. The light emitting display device according to claim 7, wherein the at least one trench is depressed from a top surface of the first planarization layer to a bottom surface of the first planarization layer.

10. The light emitting display device according to claim 7, wherein the at least one trench includes 2 to 4 trenches between the first light emitting diode and the second light emitting diode.

11. The light emitting display device according to claim 7, wherein the emission layer is disconnected between the first light emitting diode and the second light emitting diode by the trench.

12. The light emitting display device according to claim 6, further comprising:
at least one trench depressed into the first planarization layer between the first light emitting diode and the dummy anode electrode,
wherein the first light emitting diode includes:
the second planarization layer on the first planarization layer;
a first anode electrode on the second planarization layer;
the emission layer on the first anode electrode; and
the cathode electrode on the emission layer, and
wherein the second light emitting diode includes:
the second planarization layer on the first planarization layer;
a second anode electrode on the second planarization layer;
the emission layer on the second anode electrode; and
the cathode electrode on the emission layer.

13. The light emitting display device according to claim 12, wherein the at least one trench includes a first trench and a second trench disposed adjacently between the first light emitting diode and the dummy anode electrode.

14. The light emitting display device according to claim 6, further comprising:
a display area including the plurality of pixels;
a non-display area adjacent to the display area; and
a low-voltage line disposed at the non-display area,
wherein the dummy anode electrode is connected to the low-voltage line.

15. A light emitting display device comprising:
a substrate having a plurality of pixels disposed thereon;
a driving element layer on the substrate;
a first planarization layer on the driving element layer;
a second planarization layer protruding having an island shape on the first planarization layer;
an anode electrode on the second planarization layer;
an emission layer on the first planarization layer, a sidewall of the second planarization layer that is not covered by the anode electrode and the anode electrode; and
a cathode electrode on the emission layer,
wherein the anode electrode includes a transparent conductive material, and
wherein a refractive index of the second planarization layer is at most 0.2 lower than a refractive index of the anode electrode.

16. The light emitting display device according to claim 15, wherein the emission layer is further disposed on an edge portion of a top surface of the second planarization layer that is not covered by the anode electrode.

17. The light emitting display device according to claim 16, wherein a refractive index of the first planarization layer is at least 0.5 lower than the refractive index of the second planarization layer.

18. The light emitting display device according to claim 15, wherein an inclination angle of the sidewall of the second planarization layer with respect to a horizontal surface is 40 to 80 degrees.

19. The light emitting display device according to claim 15, wherein an inclination angle of the sidewall of the second planarization layer with respect to a horizontal surface is 50 to 75 degrees.
